(19) United States
(12) Patent Application Publication
(10) Pub. No.: US 2026/0018555 A1
(43) Pub. Date: Jan. 15, 2026

(54) SEMICONDUCTOR PACKAGE

(71) Applicant: SAMSUNG ELECTRONICS CO., LTD., Suwon-si (KR)

(72) Inventor: Takuya Futatsuyama, Suwon-si (KR)

(21) Appl. No.: 19/029,597

(22) Filed: Jan. 17, 2025

(30) Foreign Application Priority Data
Jul. 15, 2024 (KR) 10-2024-0093333

(51) Int. Cl. H01L 23/00; H01L 21/48; H01L 23/538; H01L 25/16; H10B 80/00

(52) U.S. Cl. CPC H01L 24/48; H01L 23/5386; H01L 24/06; H01L 24/49; H01L 25/16; H01L 21/4853; H01L 24/32; H01L 24/73; H01L 2224/06131; H01L 2224/32145; H01L 2224/32225; H01L 2224/4805; H01L 2224/48147; H01L 2224/48227; H01L 2224/49175; H01L 2224/73265; H01L 2225/06506; H01L 2225/0651; H01L 2225/06562; H01L 2924/35; H10B 80/00

(57) ABSTRACT

Provided is a semiconductor package including a package substrate having a first upper connection pad and a second upper connection pad provided on a top surface of the package substrate, a semiconductor chip disposed on the package substrate, a second semiconductor chip provided on the first semiconductor chip, a plurality of first chip pads and a plurality of second chip pads provided on top surfaces of the first semiconductor chip and the second semiconductor chip, respectively, a plurality of first conductive patterns, a plurality of second conductive patterns, and a cross conductive pattern of which both ends are connected to the first conductive pattern, wherein the cross conductive pattern is provided on a top surface of the first semiconductor chip and the second conductive pattern, and the cross conductive pattern crosses the second cross conductive pattern.

### CROSS-REFERENCE TO RELATED APPLICATION

This application is based on and claims priority under 35 U.S.C. § 119 to Korean Patent Application No. 10-2024-0093333, filed on Jul. 15, 2024, in the Korean Intellectual Property Office, the disclosure of which is incorporated by reference herein in its entirety.

### BACKGROUND

With the rapid development of the electronics industry and demands of users, electronic devices are becoming increasingly smaller and lighter, and accordingly, the semiconductor devices, which are the core components of electronic devices, have become more integrated and have larger capacities. As the demand for semiconductor devices with larger capacity increases, semiconductor packages in which a plurality of semiconductor chips are stacked are being developed.

In some semiconductor packages, a plurality of semiconductor chips are stacked, and electrical input/output is established between the plurality of semiconductor chips and a package substrate through wire bonding. However, wire bonding of the plurality of stacked semiconductor chips can result in thicker semiconductor packages, and the manufacturing process thereof becomes more complex.

### SUMMARY

The present disclosure provides a semiconductor package including a plurality of stacked semiconductor chips, in which the number of upper connection pads on a package substrate is reduced to miniaturize the semiconductor package, reduce wiring defects, and improve signal quality. In some implementations, a stacked semiconductor chip is connected to a package substrate through wires formed through patterning, rather than wire bonding, to simplify the manufacturing process and keep the semiconductor package relatively thin.

In addition, the technical goals to be achieved by the present disclosure are not limited to the technical goals mentioned above, and other technical goals may be clearly understood by one of ordinary skill in the art from the following description.

In a first general aspect, a semiconductor package includes: a package substrate having a first upper connection pad and a second upper connection pad provided on a top surface of the package substrate, a semiconductor chip disposed on the package substrate, a second semiconductor chip provided on the first semiconductor chip and laterally offset in a first direction from the first semiconductor chip, a plurality of first chip pads and a plurality of second chip pads provided on top surfaces of the first semiconductor chip and the second semiconductor chip, respectively, a plurality of first conductive patterns extending along a top surface and side surfaces of the first semiconductor chip and a top surface and side surfaces of the second semiconductor chip and connected to the first chip pad of the first semiconductor chip, the first chip pad of the second semiconductor chip, and the first upper connection pad, a plurality of second conductive patterns extending along a top surface and side surfaces of the first semiconductor chip and a top surface and side surfaces of the second semiconductor chip and connected to the second chip pad of the first semiconductor chip, the second chip pad of the second semiconductor chip, and the second upper connection pad, and a first cross conductive pattern of which both ends are connected to the first conductive pattern, wherein the first cross conductive pattern is provided on a top surface of the first semiconductor chip and the second conductive pattern, the first cross conductive pattern crosses the second cross conductive pattern, and both ends of the first cross conductive pattern are respectively connected to the plurality of first conductive patterns and are spaced apart from the second conductive pattern.

In a second general aspect, a semiconductor package includes: a package substrate having a plurality of first upper connection pads and a plurality of second upper connection pads provided on a top surface of the package substrate, a plurality of semiconductor chip stacks including a plurality of semiconductor chips stacked in a step-like shape and provided on the package substrate, wherein the plurality of semiconductor chips include a first semiconductor chip and a second semiconductor chip that are sequentially stacked, and the first semiconductor chip is provided on the package substrate, a plurality of first chip pads and a plurality of second chip pads respectively provided on top surfaces of the plurality of semiconductor chips, a plurality of first conductive patterns extending along a top surface and side surfaces of the first semiconductor chip and a top surface and side surfaces of the second semiconductor chip and connected to the first chip pad of the first semiconductor chip, the first chip pad of the second semiconductor chip, and the plurality of first upper connection pads, a plurality of second conductive patterns extending along a top surface and side surfaces of the first semiconductor chip and a top surface and side surfaces of the second semiconductor chip and connected to the second chip pad of the first semiconductor chip, the second chip pad of the second semiconductor chip, and the plurality of second upper connection pad, and a first cross conductive pattern of which both ends are connected to the first conductive pattern, wherein the first cross conductive pattern is provided on a top surface of the first semiconductor chip and the second conductive pattern, the first cross conductive pattern crosses the second conductive pattern, and both ends of the first cross conductive pattern are respectively connected to the plurality of first conductive patterns and are spaced apart from the second conductive pattern, the plurality of semiconductor chips are stacked in a step-like shape and offset from each other in a first direction, at least a portion of the first conductive pattern and at least a portion of the second conductive pattern extending on the first semiconductor chip and the second semiconductor chip extend in a first direction on a horizontal plane, and a number of the plurality of second chip pads on the first semiconductor chip is identical to a number of the plurality of second upper connection pads.

In a third general aspect, a semiconductor package includes: a package substrate having a plurality of first upper connection pads and a plurality of second upper connection pads provided on a top surface of the package substrate, a plurality of semiconductor chip stacks including a plurality of semiconductor chips stacked in a step-like shape and provided on the package substrate, wherein the plurality of semiconductor chips include a first semiconductor chip and a second semiconductor chip that are sequentially stacked, and the first semiconductor chip is provided on the package substrate, a plurality of first chip pads and a plurality of second chip pads respectively provided on top surfaces of the plurality of semiconductor chips, a plurality of first conductive patterns extending along a top surface and side surfaces of the first semiconductor chip and a top surface and side surfaces of the second semiconductor chip and connected to the first chip pad of the first semiconductor chip, the first chip pad of the second semiconductor chip, and the plurality of first upper connection pads, a plurality of second conductive patterns extending along a top surface and side surfaces of the first semiconductor chip and a top surface and side surfaces of the second semiconductor chip and connected to the second chip pad of the first semiconductor chip, the second chip pad of the second semiconductor chip, and the plurality of second upper connection pad, and a first cross conductive pattern of which both ends are connected to the first conductive pattern, wherein the first cross conductive pattern is provided on a top surface of the first semiconductor chip and the second conductive pattern, the first cross conductive pattern crosses the second conductive pattern, and both ends of the first cross conductive pattern are respectively connected to the plurality of first conductive patterns and are spaced apart from the second conductive pattern, the plurality of semiconductor chips are stacked in a step-like shape and offset from each other in a first direction, at least a portion of the first conductive pattern and at least a portion of the second conductive pattern extending on the first semiconductor chip and the second semiconductor chip extend in a first direction on a horizontal plane, a number of the plurality of second chip pads on the first semiconductor chip is identical to a number of the plurality of second upper connection pads, a first cross insulation layer is provided between the first cross conductive pattern and the second conductive pattern, the first cross insulation layer covers a top surface of the second conductive pattern, and a width of the first cross insulation layer is greater than a width of the first cross conductive pattern, and a separating insulation layer is provided on side surfaces of the first semiconductor chip and side surfaces of the second semiconductor chip.

### BRIEF DESCRIPTION OF THE DIAGRAMS

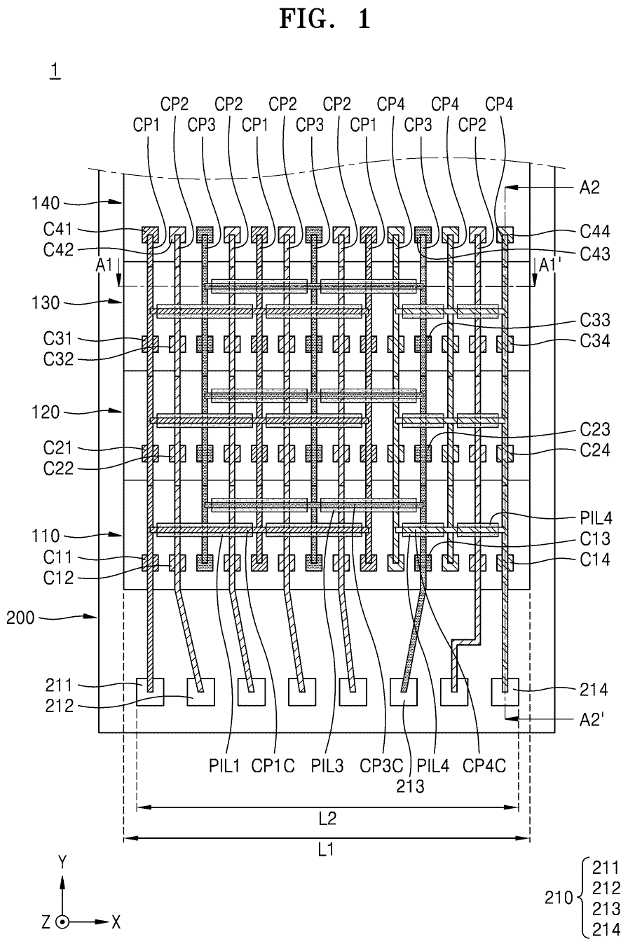

FIG. 1 is a plan view of an example of a semiconductor package.

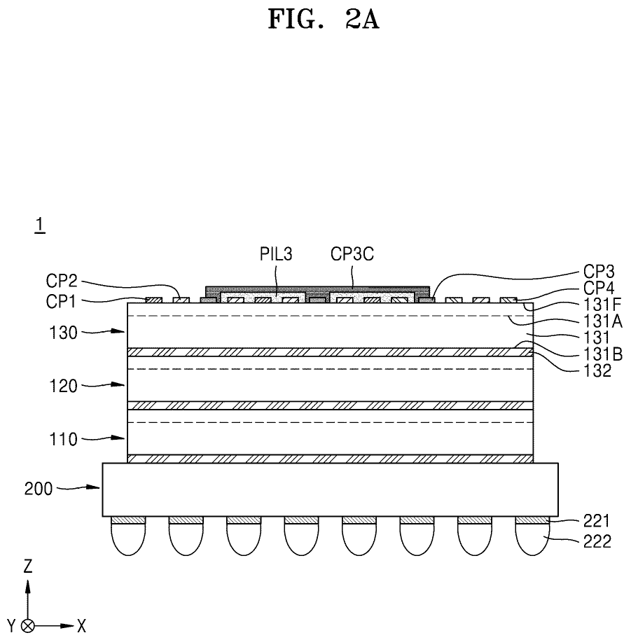

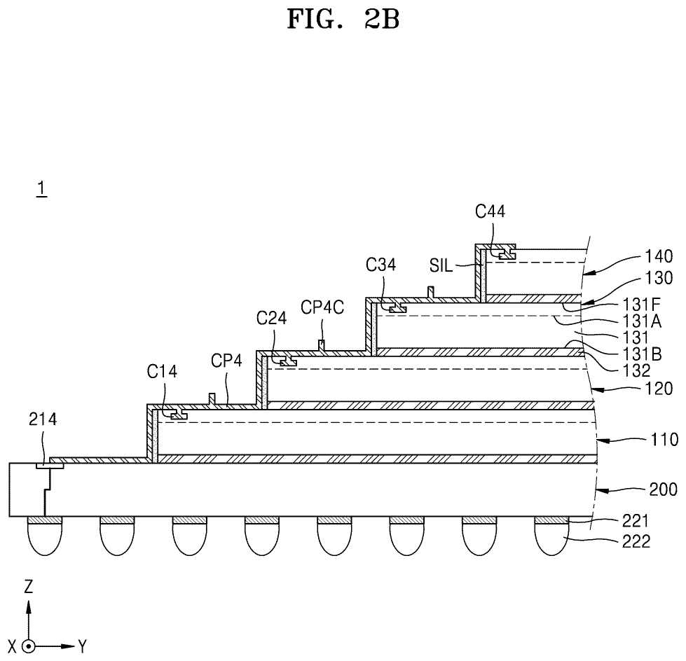

FIG. 2A is an enlarged cross-sectional view of the semiconductor package, taken along a line A1-A1′ of FIG. 1.

FIG. 2B is an enlarged cross-sectional view of the semiconductor package, taken along a line A2-A2′ of FIG. 1.

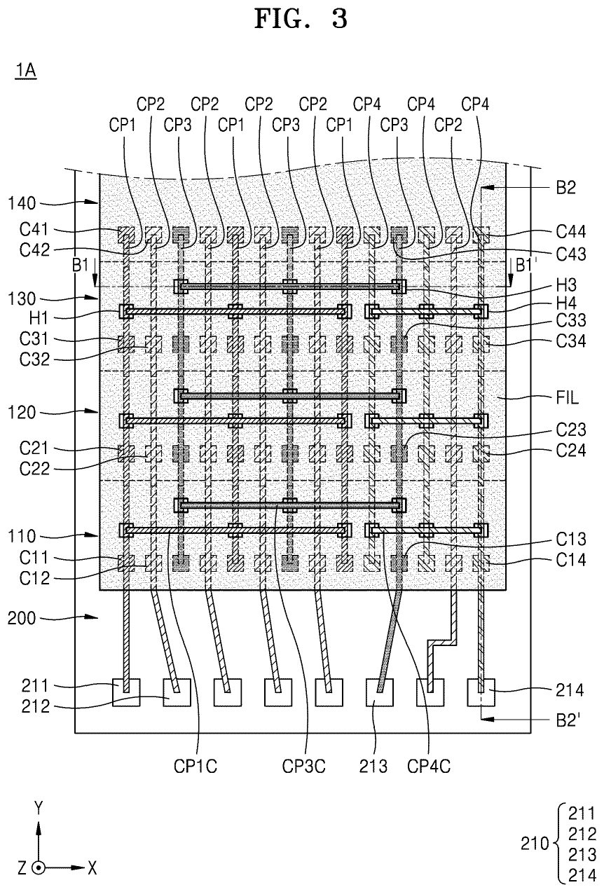

FIG. 3 is a plan view of an example of a semiconductor package.

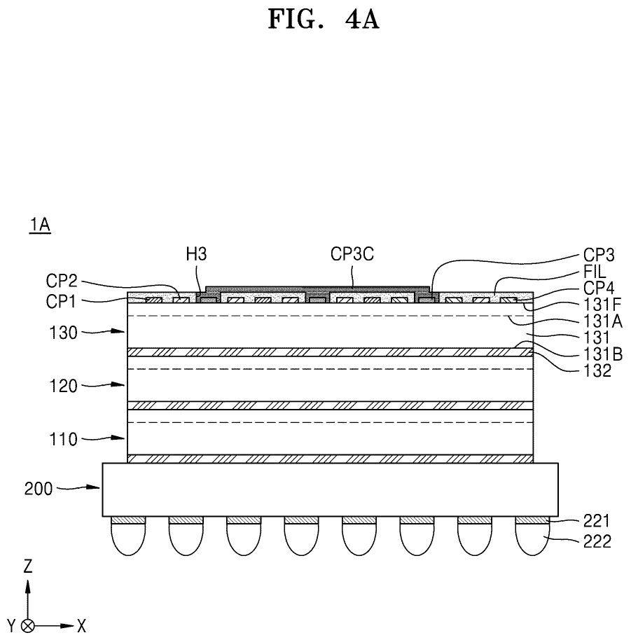

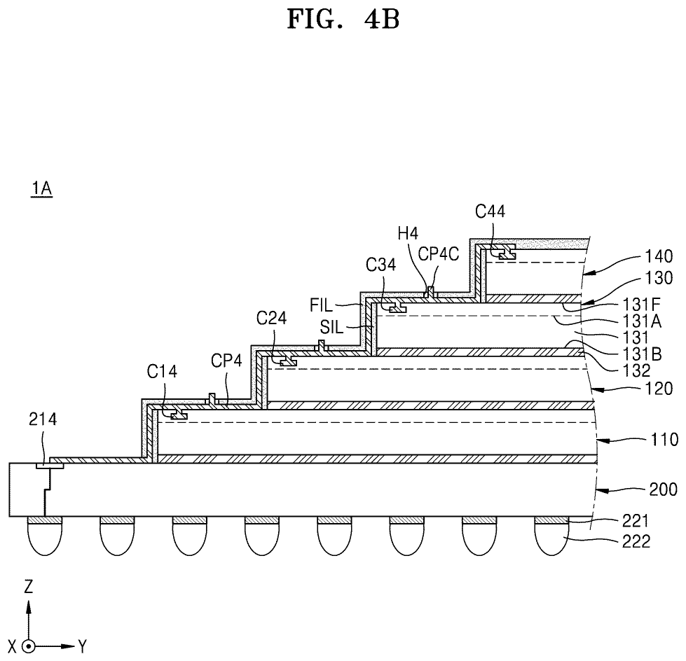

FIG. 4A is an enlarged cross-sectional view of the semiconductor package, taken along a line B1-B1′ of FIG. 3.

FIG. 4B is an enlarged cross-sectional view of the semiconductor package, taken along a line B2-B2′ of FIG. 3.

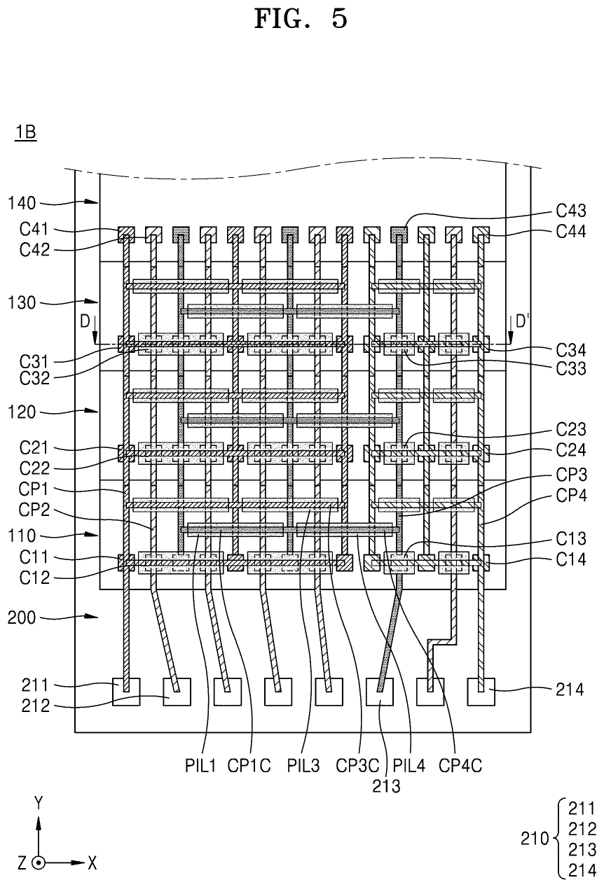

FIG. 5 is a plan view of an example of a semiconductor package.

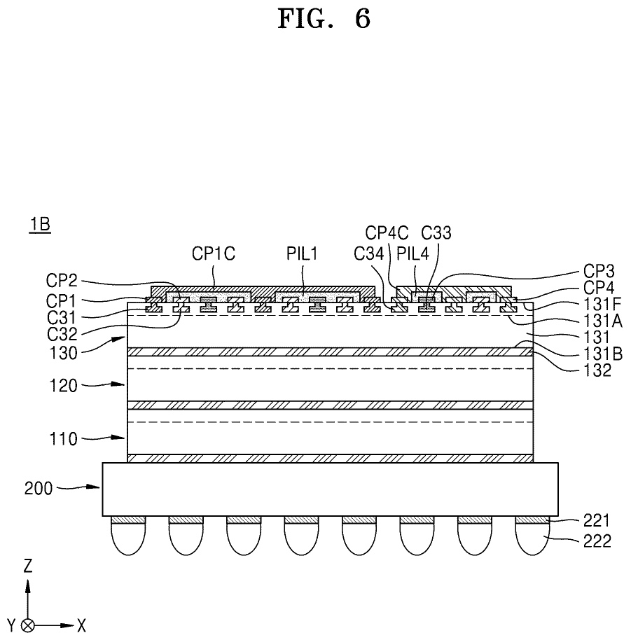

FIG. 6 is an enlarged cross-sectional view of the semiconductor package, taken along a line D-D′ of FIG. 5.

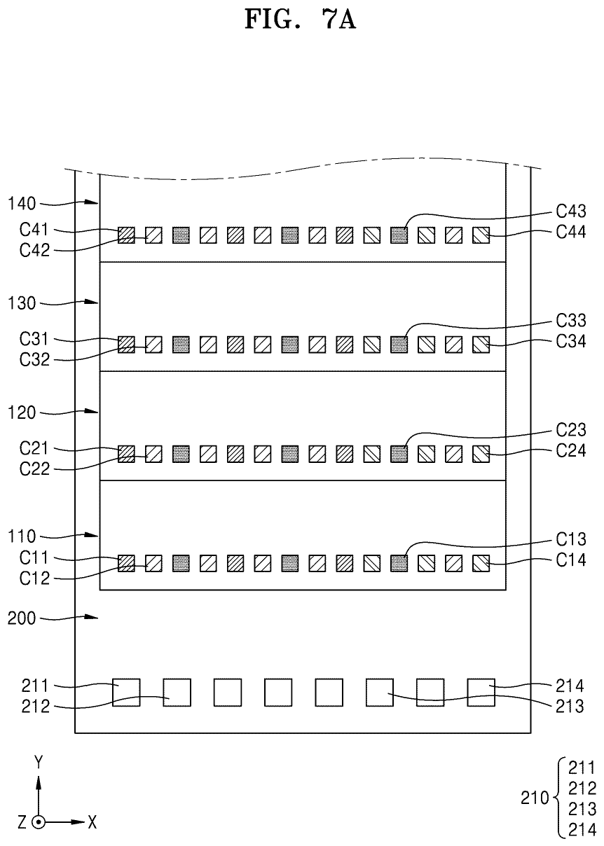

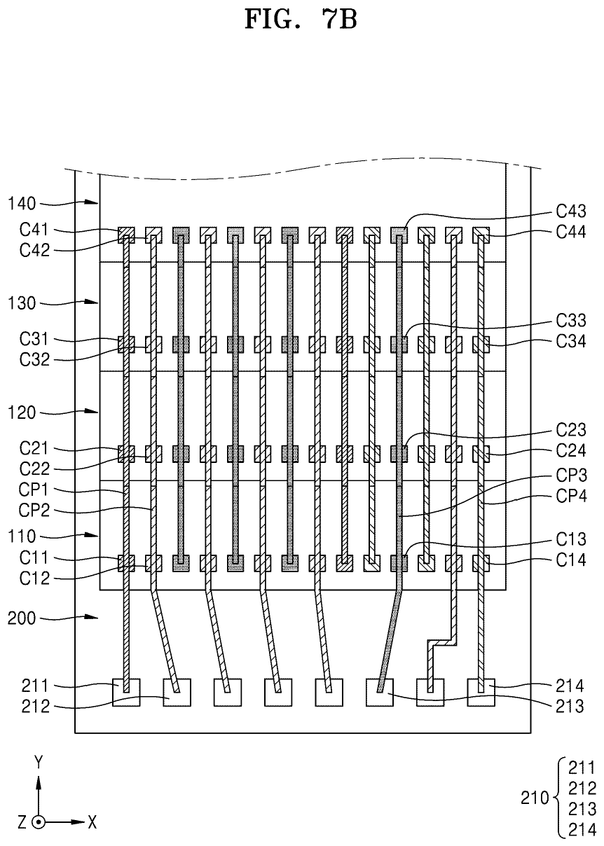

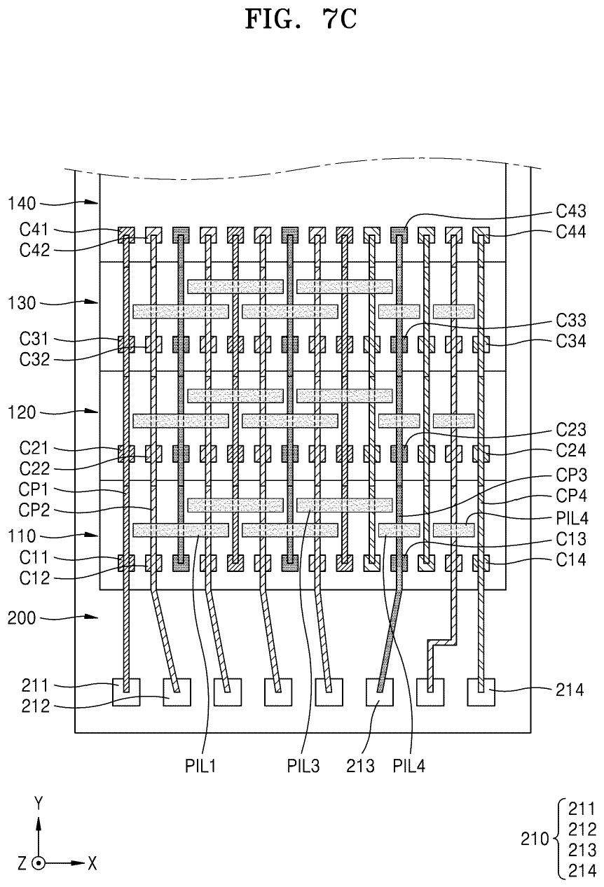

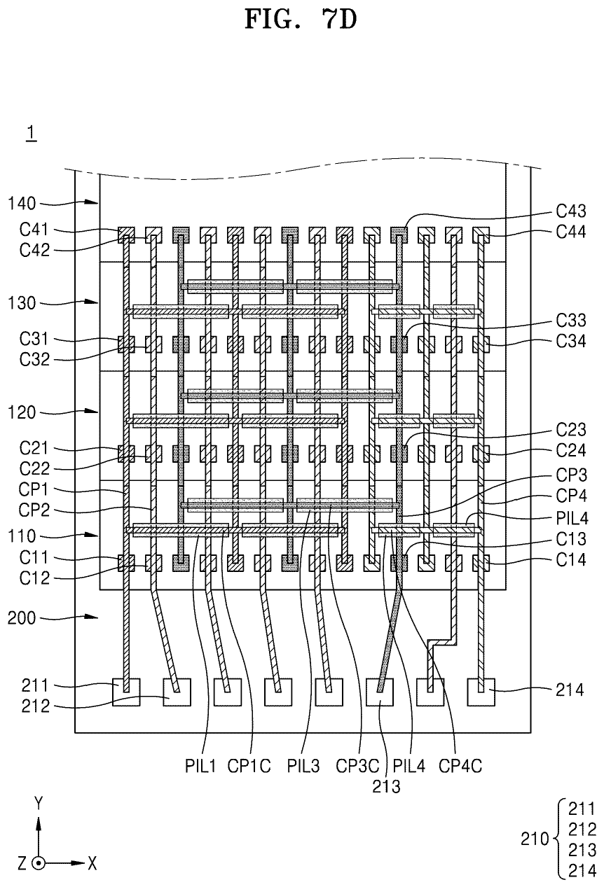

FIGS. 7A to 7D are plan views sequentially showing an example of a method for manufacturing a semiconductor package.

### DETAILED DESCRIPTION

FIG. 1 is a plan view of a semiconductor package 1. FIG. 2A is an enlarged cross-sectional view of the semiconductor package 1, taken along a line A1-A1′ of FIG. 1. FIG. 2B is an enlarged cross-sectional view of the semiconductor package 1, taken along a line A2-A2′ of FIG. 1.

Referring to FIG. 1, FIG. 2A, and FIG. 2B, the semiconductor package 1 includes a package substrate 200, a first semiconductor chip 110, a second semiconductor chip 120, a third semiconductor chip 130, and a fourth semiconductor chip 140.

A first upper connection pad 211, a second upper connection pad 212, a third upper connection pad 213, and a fourth upper connection pad 214 may be arranged on the top surface of the package substrate 200. The first upper connection pad 211, the second upper connection pad 212, the third upper connection pad 213, and the fourth upper connection pad 214 arranged on the top surface of the package substrate 200 may be collectively referred to as substrate upper connection pads 210.

The substrate upper connection pads 210 may be arranged adjacent to one edge of the top surface of the package substrate 200 and provided on the top surface of the package substrate 200. For example, as shown in FIG. 1, the first upper connection pad 211, the second upper connection pad 212, the third upper connection pad 213, and the fourth upper connection pad 214 may be arranged in a row adjacent to one edge of the package substrate 200, but the present disclosure is not limited thereto.

The first semiconductor chip 110 may be disposed on the top surface of the package substrate 200. The second semiconductor chip 120 may be disposed on the first semiconductor chip 110. The second semiconductor chip 120 may be provided on the first semiconductor chip 110 and be laterally offset from the first semiconductor chip 110. For example, the second semiconductor chip 120 may be offset in a positive second direction (+Y direction) from the first semiconductor chip 110. Similarly, the third semiconductor chip 130 may be disposed on the second semiconductor chip 120, and the third semiconductor chip 130 may be laterally offset from the second semiconductor chip 120. The fourth semiconductor chip 140 may be disposed on the third semiconductor chip 130, and the fourth semiconductor chip 140 may be laterally offset from the third semiconductor chip 130.

The first semiconductor chip 110, the second semiconductor chip 120, the third semiconductor chip 130, and the fourth semiconductor chip 140 may be collectively referred to as a semiconductor chip stack. The semiconductor chip stack may include a plurality of semiconductor chips stacked in a step-like shape.

The substrate upper connection pads 210 provided on the top surface of the package substrate 200 may be arranged in a direction opposite to the direction in which the second semiconductor chip 120 is offset from the first semiconductor chip 110, with respect to the first semiconductor chip 110. For example, with respect to the first semiconductor chip 110, the second semiconductor chip 120 may be offset in a positive second direction (+Y direction), and the substrate upper connection pads 210 of the package substrate 200 may be provided in a negative second direction (−Y direction), which is the direction opposite to the positive second direction with respect to the first semiconductor chip 110.

External connection pads 221 and external connection terminals 222 provided on the external connection pads 221 may be arranged on the bottom surface of the package substrate 200. The package substrate 200 may be connected to an external electronic device, e.g., a printed circuit board (PCB), through the external connection terminals 222. The package substrate 200 may be, for example, a PCB or a redistribution structure.

When the package substrate 200 is a PCB, the package substrate 200 may include a base layer, and the base layer may include a plurality of stacked sub-base layers. The top surface and the bottom surface of the base layer may be covered with a solder resist layer. The substrate upper connection pads 210 and the external connection pads 221 are not covered by the solder resist layer and may be exposed at the top surface and the bottom surface of the package substrate 200, respectively.

In some implementations, the base layer may include at least one material selected from among phenol resin, epoxy resin, and polyimide. For example, the base layer may include at least one material selected from among Flame Retardant 4 (FR4), tetrafunctional epoxy, polyphenylene ether, epoxy/polyphenylene oxide, bismaleimide triazine (BT), Thermount, cyanate ester, polyimide, and liquid crystal polymer.

When the package substrate 200 is a redistribution structure, the package substrate 200 may include a plurality of redistribution insulation layers and a redistribution pattern provided within the redistribution insulation layers. The redistribution pattern may include a plurality of redistribution line patterns and a plurality of redistribution via patterns. The plurality of redistribution line patterns may be provided between the plurality of redistribution insulation layers, and the plurality of redistribution via patterns may penetrate through the plurality of redistribution insulation layers and interconnect between the plurality of redistribution line patterns.

In some implementations, the redistribution insulation layer may include an insulation material, for example, photo imageable dielectric (PID) resin. In this case, the redistribution insulation layer may further include an inorganic filler. The redistribution pattern may include a conductive material, e.g., Cu, aluminum (A1), silver (Ag), tin (Sn), gold (Au), nickel (Ni), lead (Pb), titanium (Ti), or alloys thereof.

In this specification, as shown in FIG. 2B, the electrical connection between the substrate upper connection pads 210 of the package substrate 200 and the external connection pads 221 provided on the bottom surface of the package substrate 200 is schematically illustrated. A first chip pad C11, a second chip pad C12, a third chip pad C13, and a fourth chip pad C14 of the first semiconductor chip 110 may be arranged on the top surface of the first semiconductor chip 110. The first chip pad C11, the second chip pad C12, the third chip pad C13, and the fourth chip pad C14 of the first semiconductor chip 110 may be collectively referred to as first semiconductor chip pads. For example, the first semiconductor chip pads of the first semiconductor chip 110 may be arranged sequentially in one direction on the first semiconductor chip 110 as shown in FIG. 1, but the arrangement manner of the first semiconductor chip pads of the first semiconductor chip 110 is not limited thereto.

The first semiconductor chip pads may be arranged on the top surface of the first semiconductor chip 110 exposed due to the offset of the second semiconductor chip 120. In other words, the first semiconductor chip pads may be located on an exposed portion of the top surface of each of the first semiconductor chips 110 of the semiconductor chip stack stacked in a step-like shape. The first semiconductor chip pads may be exposed upward from a passivation layer provided on the top surface of the first semiconductor chip 110. The first semiconductor chip pads exposed from the passivation layer may be connected to a first conductive pattern CP1. This may also be applied to second semiconductor chip pads of the second semiconductor chip 120, third semiconductor chip pads of the third semiconductor chip 130, and fourth semiconductor chip pads of the fourth semiconductor chip 140 to be described below.

A first chip pad C21, a second chip pad C22, a third chip pad C23, and a fourth chip pad C24 of the second semiconductor chip 120 may be arranged on the top surface of the second semiconductor chip 120. The first chip pad C21, the second chip pad C22, the third chip pad C23, and the fourth chip pad C24 of the second semiconductor chip 120 may be collectively referred to as the second semiconductor chip pads.

A first chip pad C31, a second chip pad C32, a third chip pad C33, and a fourth chip pad C34 of the third semiconductor chip 130 may be arranged on the top surface of the third semiconductor chip 130. The first chip pad C31, the second chip pad C32, the third chip pad C33, and the fourth chip pad C34 of the third semiconductor chip 130 may be collectively referred to as the third semiconductor chip pads.

A first chip pad C41, a second chip pad C42, a third chip pad C43, and a fourth chip pad C44 of the fourth semiconductor chip 140 may be arranged on the top surface of the fourth semiconductor chip 140. The first chip pad C41, the second chip pad C42, the third chip pad C43, and the fourth chip pad C44 of the fourth semiconductor chip 140 may be collectively referred to as the fourth semiconductor chip pads.

The arrangement order of the first semiconductor chip pads provided on the first semiconductor chip 110 in one direction may be identical to the arrangement order of chip pads provided on another semiconductor chip in the one direction. For example, the arrangement order of the first chip pad C11, the second chip pad C12, the third chip pad C13, and the fourth chip pad C14 included in the first semiconductor chip pads arranged on the first semiconductor chip 110 in the positive first direction (+X direction) may be identical to the arrangement order of the first chip pad C21, the second chip pad C22, the third chip pad C23, and the fourth chip pad C24 included in the second semiconductor chip pads arranged on the second semiconductor chip 120 in the positive first direction (+X direction). In other words, when the first semiconductor chip pads arranged on the first semiconductor chip 110 in the positive first direction +X direction are arranged in the order of the first chip pad C11, the second chip pad C12, the third chip pad C13, the second chip pad C12, the first chip pad C11, the second chip pad C12, the third chip pad C13, the second chip pad C12, the first chip pad C11, the fourth chip pad C14, the third chip pad C13, the fourth chip pad C14, the second chip pad C12, and the fourth chip pad C14, the second semiconductor chip pads may also be arranged on the second semiconductor chip 120 in the positive first direction (+X direction) in the same order. This may be applied to the third semiconductor chip pads arranged on the third semiconductor chip 130 and the fourth semiconductor chip arranged on the fourth semiconductor chip 140.

Some of the substrate upper connection pads 210 connected to the first conductive pattern CP1 may be first upper connection pads 211, some of the substrate upper connection pads 210 connected to a second conductive pattern CP2 may be second upper connection pads 212, some of the substrate upper connection pads 210 connected to a third conductive pattern CP3 may be third upper connection pads 213, and some of the substrate upper connection pads 210 connected to a fourth conductive pattern CP4 may be fourth upper connection pads 214.

As shown in FIGS. 2A and 2B, the third semiconductor chip 130 may include a third semiconductor substrate 131. The third semiconductor substrate 131 may include, for example, silicon (Si). Alternatively, the third semiconductor substrate 131 may include a semiconductor element, such as germanium (Ge), or a compound semiconductor, such as silicon carbide (SiC), gallium arsenide (GaAs), indium arsenide (InAs), and indium phosphide (InP). Alternatively, the third semiconductor substrate 131 may have a silicon-on-insulator (SOI) structure. For example, the third semiconductor substrate 131 may include a buried oxide (BOX) layer. The third semiconductor substrate 131 may include a conductive region, e.g., a well doped with an impurity. The third semiconductor substrate 131 may have various device isolation structures such as a shallow trench isolation (STI) structure. The third semiconductor substrate 131 may have a third active surface 131A and a third inactive surface opposite to the third active surface 131A. The third inactive surface may be referred to as a third substrate back surface 131B.

A semiconductor device including a plurality of individual devices of various types may be formed on the third active surface 131A of the third semiconductor chip 130. The plurality of individual devices may include various microelectronic devices, e.g., a metal-oxide-semiconductor field effect transistor (MOSFET) such as a complementary metal-insulator-semiconductor (CMOS) transistor, a floating gate transistor, a system large scale integration (LSI), a micro-electro-mechanical system (MEMS), an active device, a passive device, etc.

The plurality of individual devices may be electrically connected to the conductive region of the third semiconductor substrate 131. Also, the individual devices may each be electrically separated from other neighboring individual devices by an insulating film.

For example, the third semiconductor chip 130 may be a memory semiconductor chip. In some implementations, the memory semiconductor chip may be a non-volatile memory semiconductor device such as flash memory, phase-change random access memory (PRAM), magnetoresistive random access memory (MRAM), ferroelectric random access memory (FeRAM), or resistive random access memory (RRAM). The flash memory may be, for example, V-NAND flash memory. In some implementations, the memory semiconductor device may be a volatile memory device such as dynamic random access memory (DRAM) or static random access memory (SRAM).

The third semiconductor chip 130 may include a third substrate front surface 131F and the third substrate back surface 131B. A surface adjacent to the third active surface 131A of the third semiconductor chip 130 may be referred to as the third substrate front surface 131F, and a surface opposite to the third substrate front surface 131F may be referred to as the third substrate back surface 131B. In this specification, a surface facing upward in the vertical direction may be referred to as the top surface, and a surface facing downward in the vertical direction may be referred to as the bottom surface. In other words, the top surface of the third semiconductor chip 130 may be the third substrate front surface 131F, and the bottom surface of the third semiconductor chip 130 may be the third substrate back surface 131B. The third semiconductor chip 130 may be disposed on the package substrate 200 such that the third active surface 131A of the third semiconductor chip 130 is located farther from the package substrate 200 than the third substrate back surface 131B, which is the third inactive surface.

A third adhesive film 132 may be disposed on the bottom surface of the third semiconductor chips 130, and thus the third semiconductor chip 130 may be attached to a structure therebelow. As shown in FIG. 2A, the third adhesive film 132 may provide on the bottom surface of the third semiconductor chip 130 and may be attached to the second semiconductor chip 120. The third adhesive film 132 may include a non-conductive film (NCF) or a non-conductive paste (NCP).

A first adhesive film may be disposed on the bottom surface of the first semiconductor chip 110, and the first adhesive film may be attached to the top surface of the package substrate 200. Likewise, a second adhesive film may be disposed on the bottom surface of the second semiconductor chip 120, and the second adhesive film may be attached to the top surface of the first semiconductor chip 110.

The descriptions of the third semiconductor substrate 131, the third active surface 131A, the third substrate front surface 131F, the third substrate back surface 131B, and the third adhesive film 132 included in the third semiconductor chip 130 given above may be applied in the same manner to the first semiconductor chip 110, the second semiconductor chip 120, and the fourth semiconductor chip 140.

The first conductive pattern CP1, the second conductive pattern CP2, the third conductive pattern CP3, and the fourth conductive pattern CP4 may extend along the top surface and side surfaces of the first semiconductor chip 110, the top surface and side surfaces of the second semiconductor chip 120, the top surface and side surfaces of the third semiconductor chip 130, and the top surface and side surfaces of the fourth semiconductor chip 140, respectively. A portion of the first conductive pattern CP1, a portion of the second conductive pattern CP2, a portion of the third conductive pattern CP3, and a portion of the fourth conductive pattern CP4 may extend from the top surface and the side surfaces of the first semiconductor chip 110 to the top surface of the package substrate 200.

The first conductive pattern CP1, the second conductive pattern CP2, the third conductive pattern CP3, and the fourth conductive pattern CP4 extended to the top surface of the package substrate 200 may be connected to corresponding ones of the first upper connection pad 211, the second upper connection pad 212, the third upper connection pad 213, and the fourth upper connection pad 214, respectively.

As shown in FIG. 2B, a separating insulation layer SIL may be provided on side surfaces of the first semiconductor chip 110, the second semiconductor chip 120, the third semiconductor chip 130, and the fourth semiconductor chip 140. The separating insulation layer SIL may be provided between the fourth conductive pattern CP4 and the first semiconductor chip 110, the second semiconductor chip 120, the third semiconductor chip 130, and the fourth semiconductor chip 140. In other words, the separating insulation layer SIL may be provided between the first conductive pattern CP1, the second conductive pattern CP2, the third conductive pattern CP3, and the fourth conductive pattern CP4 and the first semiconductor chip 110, the second semiconductor chip 120, the third semiconductor chip 130, and the fourth semiconductor chip 140. Therefore, the first conductive pattern CP1, the second conductive pattern CP2, the third conductive pattern CP3, and the fourth conductive pattern CP4 may extend on the separating insulation layer SIL.

As shown in FIG. 2B, the separating insulation layer SIL may separate the fourth conductive pattern CP4 from the side surfaces of the first semiconductor chip 110, the side surfaces of the second semiconductor chip 120, the side surfaces of the third semiconductor chip 130, and the side surfaces of the fourth semiconductor chip 140. Since the separating insulation layer SIL is provided over the side surfaces of the first semiconductor chip 110, the second semiconductor chip 120, the third semiconductor chip 130, and the fourth semiconductor chip 140, not only the fourth conductive pattern CP4, but also the first conductive pattern CP1, the second conductive pattern CP2, and the third conductive pattern CP3 may be spaced apart from the side surfaces of the first semiconductor chip 110, the second semiconductor chip 120, the third semiconductor chip 130, and the fourth semiconductor chip 140 by the separating insulation layer SIL.

For example, as shown in FIG. 2B, the fourth conductive pattern CP4 may extend along the top surface and the side surfaces of the first semiconductor chip 110, the top surface and the side surfaces of the second semiconductor chip 120, the top surface and the side surfaces of the third semiconductor chip 130, and the top surface and the side surfaces of the fourth semiconductor chip 140. Since the separating insulation layer SIL is provided on the side surfaces of the first semiconductor chip 110, the side surfaces of the second semiconductor chip 120, the side surfaces of the third semiconductor chip 130, and the side surfaces of the fourth semiconductor chip 140, the fourth conductive pattern CP4 may extend on the top surface of the first semiconductor chip 110, the top surface of the second semiconductor chip 120, the top surface of the third semiconductor chip 130, the top surface of the fourth semiconductor chip 140, and the separating insulation layer SIL.

The separating insulation layer SIL may include an organic material such as a polyimide, a polymer, and a polyimide silicone, an ultraviolet (UV) curable material, a thermosetting liquid crystal polymer, a combination thereof, or similar materials known to one of ordinary skill in the art.

Alternatively, in some implementations, the separating insulation layer SIL may include a polymer film and metal-containing particles dispersed in the polymer film. The polymer film may include various materials, e.g., an epoxy mold compound or parylene. The metal-containing particles may include a metal oxide, a metal nitride, a metal carbide, or a metal sulfide or may be metal particles coated with an insulation material. Various metals may be included in the metal-containing particles, e.g., aluminum, magnesium, iron, manganese, copper, chromium, cobalt, nickel, etc. In some implementations, the separating insulation layer SIL may be formed by using deposition, dispensing, coating, or screen printing techniques.

FIG. 2B shows a fourteenth column conductive pattern, which is the fourth conductive pattern CP4 and described below, and the fourteenth column conductive pattern may extend to the top surface of the package substrate 200 and be connected to an eighth column conductive pattern, which is the fourth upper connection pad 214 and described below.

For example, as shown in FIG. 1, although a twelfth column conductive pattern is the fourth conductive pattern CP4 like the fourteenth column conductive pattern, the twelfth column conductive pattern may not extend to the top surface of the package substrate 200.

The first conductive pattern CP1 may be disposed to extend on the first chip pad C41 of the fourth semiconductor chip 140, the first chip pad C31 of the third semiconductor chip 130, the first chip pad C21 of the second semiconductor chip 120, and the first chip pad C11 of the first semiconductor chip 110. Also, the first conductive pattern CP1 may be connected to the first chip pad C41 of the fourth semiconductor chip 140, the first chip pad C31 of the third semiconductor chip 130, the first chip pad C21 of the second semiconductor chip 120, and the first chip pad C11 of the first semiconductor chip 110.

In this specification, a conductive pattern in the most negative direction with respect to the first direction (+X direction) may be referred to as a first column conductive pattern. As shown in FIG. 1, the first column conductive pattern, a fifth column conductive pattern, and a ninth column conductive pattern may be first conductive patterns CP1. A second column conductive pattern, a fourth column conductive pattern, a sixth column conductive pattern, the eighth column conductive pattern, and a thirteenth column conductive pattern may be second conductive patterns CP2. A third column conductive pattern, a seventh column conductive pattern, and an eleventh column conductive pattern may be third conductive patterns CP3. A tenth column conductive pattern, the twelfth column conductive pattern, and the fourteenth column conductive pattern may be fourth conductive patterns CP4.

In this specification, an upper connection pad in the most negative direction with respect to the first direction (+X direction) may be referred to as a first column connection pad. In other words, the first column connection pad may be the first upper connection pad 211, a second column connection pad, a third column connection pad, a fourth column connection pad, a fifth column connection pad, and a seventh column connection pad may be the second upper connection pads 212, respectively, a sixth column connection pad may be the third upper connection pad 213, a sixth column connection pad may be the third upper connection pad 213, and an eighth column connection pad may be the fourth upper connection pad 214.

In this specification, a chip pad in the most negative direction with respect to the first direction (+X direction) may be referred to as a first column chip pad. In the first semiconductor chip 110, a first column chip pad, a fifth column chip pad, and a ninth column chip pad may be first chip pads C11. A second column chip pad, a fourth column chip pad, a sixth column chip pad, an eighth column chip pad, and a thirteenth column chip pad may be second chip pads C12. A third column chip pad, a seventh column chip pad, and an eleventh column chip pad may be third chip pads C13. A tenth column chip pad, a twelfth column chip pad, and a fourteenth column chip pad may be fourth chip pads C14.

It will be understood that, since the types and the arrangement order of conductive patterns, the types and the arrangement order of upper connection pads, and the types and the arrangement order of chip pads in this specification may be changed at any time depending on the design of a semiconductor chip and a semiconductor package including the semiconductor chip, the examples in this specification are intended to aid understanding and are not intended to limit the inventive concept.

The first column conductive pattern may extend from the first column chip pad of the first semiconductor chip 110 to the top surface of the first semiconductor chip 110, the separating insulation layer SIL provided on the side surfaces of the first semiconductor chip 110, and the top surface of the package substrate 200. As shown in FIG. 1, the first column conductive pattern may be connected to the first upper connection pad 211, which is the first column connection pad. Unlike the first column conductive pattern, the fifth column conductive pattern and the ninth column conductive pattern, which are the first conductive patterns CP1, may not extend from the fifth column chip pad of the first semiconductor chip 110 and the ninth column chip pad of the first semiconductor chip 110, respectively, to the top surface of the package substrate 200.

The second column conductive pattern is the second conductive pattern CP2, and the second column conductive pattern may extend from the second column chip pad of the first semiconductor chip 110 to the top surface of the first semiconductor chip 110, the separating insulation layer SIL provided on the side surfaces of the first semiconductor chip 110, and the top surface of the package substrate 200. The second column conductive pattern may be connected to the second upper connection pad 212, which is the second column connection pad. In other words, a plurality of second conductive patterns CP2 may extend from the second chip pad C12 of the first semiconductor chip 110 to the top surface and the side surfaces of the first semiconductor chip 110 and the top surface of the package substrate 200, and the plurality of second conductive patterns CP2 may each be connected to the second upper connection pad 212.

The third column conductive pattern is the third conductive pattern CP3, the third column conductive pattern may not extend from the third column chip pad of the first semiconductor chip 110 to the top surface of the package substrate 200, and the same may be applied to the seventh column conductive pattern. However, the eleventh column conductive pattern, which is the third conductive pattern CP3, may extend from the eleventh column chip pad of the first semiconductor chip 110 to the top surface and the side surfaces of the first semiconductor chip 110 and the top surface of the package substrate 200, and the eleventh column conductive pattern may be connected to the third upper connection pad 213, which is the sixth column connection pad.

The tenth column conductive pattern is the fourth conductive pattern CP4, and the tenth column conductive pattern may not extend from the tenth column chip pad of the first semiconductor chip 110 to the top surface of the package substrate 200. Also, the twelfth column conductive pattern, which is the fourth conductive pattern CP4, may not extend from the tenth column chip pad of the first semiconductor chip 110 to the top surface of the package substrate 200. However, the fourteenth column conductive pattern, which is the fourth conductive pattern CP4, may extend from the fourteenth column chip pad of the first semiconductor chip 110 to the top surface of the first semiconductor chip 110, the separating insulation layer SIL provided on the side surfaces of the first semiconductor chip 110, and the top surface of the package substrate 200, and the fourteenth column conductive pattern may be connected to the fourth upper connection pad 214, which is the eighth column connection pad.

Conductive patterns extending from the first semiconductor chip pads of the first semiconductor chip 110 to the substrate upper connection pads 210 arranged on the package substrate 200 may extend in straight lines from the first semiconductor chip pads to the substrate upper connection pads 210, respectively, may extend in straight lines at an angle, or may include bent portions.

For example, the first column chip pad on the first semiconductor chip 110 may be connected to the first conductive pattern CP1 extending along a straight line to a corresponding first column upper connection pad. The second column chip pad on the first semiconductor chip 110 may be connected to the second conductive pattern CP2 extending along a diagonal straight line to a corresponding second column upper connection pad. The thirteenth column chip pad on the first semiconductor chip 110 may be connected to the second conductive pattern CP2 extending to a corresponding seventh column upper connection pad and including a bent portion.

In some implementations, conductive wires may be provided to extend from the first semiconductor chip pads of the first semiconductor chip 110 and be connected to substrate upper connection pads 210 arranged on the package substrate 200. The conductive wires may interconnect the first semiconductor chip pads of the first semiconductor chip 110 and the substrate upper connection pads 210, respectively. In other words, while the connection relationship between the first semiconductor chip pads of the first semiconductor chip 110 and the substrate upper connection pads 210 described with reference to FIG. 1 is being maintained, the first semiconductor chip pads of the first semiconductor chip 110 and the substrate upper connection pads 210 may be connected to each other via conductive wires. For example, the first column chip pad of the first semiconductor chip 110 and the first column connection pad of the package substrate 200 may be connected to each other via a conductive wire. The conductive wire may be referred to as a bonding wire.

The first column conductive pattern and the ninth column conductive pattern are both the first conductive patterns CP1 and may be connected to each other via a first cross conductive pattern CP1C. For example, the first cross conductive pattern CP1C may be disposed between the first column conductive pattern and the ninth column conductive pattern arranged on the first semiconductor chip 110. In the lengthwise direction of the first cross conductive pattern CP1C, both ends of the first cross conductive pattern CP1C may be located on the first column conductive pattern and the ninth column conductive pattern, which are the first conductive patterns CP1. The first cross conductive pattern CP1C may interconnect between first conductive patterns CP1 arranged on the same semiconductor chip. The first cross conductive pattern CP1C may cross the fifth column conductive pattern, and the first cross conductive pattern CP1C may extend and be connected to the first conductive pattern CP1.

As the first column conductive pattern, the fifth column conductive pattern, and the ninth column conductive pattern are connected via the first cross conductive pattern CP1C, some of the first column conductive pattern, the fifth column conductive pattern, and the ninth column conductive pattern may extend to the substrate upper connection pads 210, and the rest of the first column conductive pattern, the fifth column conductive pattern, and the ninth column conductive pattern may not extend to the substrate upper connection pads 210. For example, the first column conductive pattern may extend to the first column upper connection pad, but the fifth column conductive pattern and the ninth column conductive pattern may not extend to the substrate upper connection pads 210. This is because the first column conductive pattern, the fifth column conductive pattern, and the ninth column conductive pattern are connected via the first cross conductive pattern CP1C.

The first cross conductive pattern CP1C disposed on the first semiconductor chip 110 may be spaced apart from second to fourth column conductive patterns and sixth to eighth column conductive patterns. The first cross conductive pattern CP1C on the first semiconductor chip 110 may cross second to eighth column conductive patterns. A first cross insulation layer PIL1 to be described below may be provided between the first cross conductive pattern CP1C and the second to fourth column conductive patterns and the sixth to eighth column conductive patterns.

For example, on the first semiconductor chip 110, the second semiconductor chip 120, the third semiconductor chip 130, and the fourth semiconductor chip 140, the first conductive pattern CP1, the second conductive pattern CP2, the third conductive pattern CP3, and the fourth conductive pattern CP4 may extend in the second direction (Y direction). On the first semiconductor chip 110, the second semiconductor chip 120, the third semiconductor chip 130, and the fourth semiconductor chip 140, the first cross conductive pattern CP1C may extend in a direction different from the direction in which the first conductive pattern CP1, the second conductive pattern CP2, the third conductive pattern CP3, and the fourth conductive pattern CP4 extend. For example, the first cross conductive pattern CP1C may extend in the first direction (X direction) perpendicular to the second direction.

However, in some implementations, the first cross conductive pattern CP1C may extend in a direction with components of both the first direction and the second direction. In other words, the first cross conductive pattern CP1C may extend in a direction different from the first direction, but may also extend in a direction different from the second direction. In other words, the first cross conductive pattern CP1C may extend in the first direction or may extend in a direction oblique to the second direction.

A third cross conductive pattern CP3C may interconnect between third conductive patterns CP3 provided on the same semiconductor chip. All of the third column conductive pattern, the seventh column conductive pattern, and the eleventh column conductive pattern are third conductive patterns CP3 and may be connected via the third cross conductive pattern CP3C. For example, the third cross conductive pattern CP3C may be disposed between the third column conductive pattern and the eleventh column conductive pattern arranged on the first semiconductor chip 110. Since the third cross conductive pattern CP3C extends from the third column conductive pattern to the eleventh column conductive pattern, both ends of the third cross conductive pattern CP3C may be located on the eleventh column conductive pattern and the third column conductive pattern, which are the third conductive patterns CP3, based on the lengthwise direction of the third cross conductive pattern CP3C. As the third cross conductive pattern CP3C crosses the seventh column conductive pattern, the third cross conductive pattern CP3C and the seventh column conductive pattern may be connected to each other.

As the third column conductive pattern, the seventh column conductive pattern, and the eleventh column conductive pattern are connected via the first cross conductive pattern CP1C, some of the third column conductive pattern, the seventh column conductive pattern, and the eleventh column conductive pattern may extend to the substrate upper connection pads 210, and the rest of the third column conductive pattern, the seventh column conductive pattern, and the eleventh column conductive pattern may not extend to the substrate upper connection pads 210. For example, the eleventh column conductive pattern may extend to the sixth column upper connection pad, but the third column conductive pattern and the seventh column conductive pattern may not extend to the substrate upper connection pads 210. This is because the third column conductive pattern, the seventh column conductive pattern, and the eleventh column conductive pattern are connected via the third cross conductive pattern CP3C.

The third cross conductive pattern CP3C on the first semiconductor chip 110 may be spaced apart from fourth to sixth column conductive patterns and eighth to tenth column conductive patterns. The third cross conductive pattern CP3C on the first semiconductor chip 110 may cross fourth to tenth column conductive patterns. A third cross insulation layer PIL3 to be described below may be provided between the third cross conductive pattern CP3C and the fourth to sixth column conductive patterns and between the third cross conductive pattern CP3C and the eighth to tenth column conductive patterns. The description of the extension direction of the third cross conductive pattern CP3C may be substantially identical to the description of the extension direction of the first cross conductive pattern CP1C.

A fourth cross conductive pattern CP4C may interconnect between the fourth conductive patterns CP4 provided on the same semiconductor chip. The tenth column conductive pattern, the twelfth column conductive pattern, and the fourteenth column conductive pattern are fourth conductive patterns CP4 and may be connected via the fourth cross conductive pattern CP4C. For example, the fourth cross conductive pattern CP4C may be disposed between the tenth column conductive pattern and the fourteenth column conductive pattern arranged on the first semiconductor chip 110. Since the fourth cross conductive pattern CP4C extends from the tenth column conductive pattern to the fourteenth column conductive pattern, both ends of the fourth cross conductive pattern CP4C may be located on the tenth column conductive pattern and the fourteenth column conductive pattern, which are the fourth conductive patterns CP4, based on the lengthwise direction of the fourth cross conductive pattern CP4C. As the fourth cross conductive pattern CP4C crosses the twelfth column conductive pattern, the fourth cross conductive pattern CP4C and the twelfth column conductive pattern may be connected to each other.

As the tenth column conductive pattern, the twelfth column conductive pattern, and the fourteenth column conductive pattern are connected via the first cross conductive pattern CP1C, some of the tenth column conductive pattern, the twelfth column conductive pattern, and the fourteenth column conductive pattern may extend to the substrate upper connection pads 210, and the rest of the tenth column conductive pattern, the twelfth column conductive pattern, and the fourteenth column conductive pattern may not extend to the substrate upper connection pads 210. For example, the fourteenth column conductive pattern may extend to the eighth column upper connection pad, but the tenth column conductive pattern and the twelfth column conductive pattern may not extend to the substrate upper connection pads 210. This is because the tenth column conductive pattern, the twelfth column conductive pattern, and the fourteenth column conductive pattern are connected via the fourth cross conductive pattern CP4C.

The fourth cross conductive pattern CP4C on the first semiconductor chip 110 may be spaced apart from the eleventh column conductive pattern and the thirteenth conductive pattern. The fourth cross conductive pattern CP4C on the first semiconductor chip 110 may cross the eleventh column conductive pattern and the thirteenth column conductive pattern. A fourth cross insulation layer PIL4 to be described below may be provided between the fourth cross conductive pattern CP4C and the eleventh column conductive pattern and the thirteenth conductive pattern. The description of the extension direction of the fourth cross conductive pattern CP4C may be substantially identical to the description of the extension direction of the first cross conductive pattern CP1C.

The descriptions given above of the first cross conductive pattern CP1C, the third cross conductive pattern CP3C, and the fourth cross conductive pattern CP4C provided on the first semiconductor chip 110 may be substantially identical to descriptions of the first cross conductive pattern CP1C, the third cross conductive pattern CP3C, and the fourth cross conductive pattern CP4C provided on the second semiconductor chip 120 and the third semiconductor chip 130.

The first cross insulation layer PIL1, the third cross insulation layer PIL3, and the fourth cross insulation layer PIL4 may separate the first cross conductive pattern CP1C, the third cross conductive pattern CP3C, and the fourth cross conductive pattern CP4C corresponding thereto from other conductive patterns, respectively.

For example, as shown in FIG. 2A, on the third semiconductor chip 130, the third cross conductive pattern CP3C may pass over the fourth to sixth column conductive patterns and the eighth to tenth column conductive patterns, and the third cross insulation layer PIL3 may fill spaces between the third cross conductive pattern CP3C and wires other than the third conductive pattern CP3. Therefore, the third cross insulation layer PIL3 may separate the third cross conductive pattern CP3C from the wires other than the third conductive pattern CP3.

Since the first cross conductive pattern CP1C is provided on the first cross insulation layer PIL1, the first cross insulation layer PIL1 may separate the first cross conductive pattern CP1C from other conductive patterns. For example, the first cross insulation layer PIL1 may separate the first cross conductive pattern CP1C from the second column conductive pattern, the third column conductive pattern, the fourth column conductive pattern, the sixth column conductive pattern, the seventh column conductive pattern, and the eighth column conductive pattern.

The first cross insulation layer PIL1, the third cross insulation layer PIL3, and the fourth cross insulation layer PIL4 may be provided on the first cross conductive pattern CP1C, the third cross conductive pattern CP3C, and the fourth cross conductive pattern CP4C, respectively, to separate the first cross conductive pattern CP1C, the third cross conductive pattern CP3C, and the fourth cross conductive pattern CP4C from other conductive patterns to prevent electric problems such as a short circuit.

As shown in FIG. 2A, the third cross conductive pattern CP3C may cross the seventh column conductive pattern, which is the third conductive pattern CP3, while extending from the third column conductive pattern to the eleventh column conductive pattern. As the third cross conductive pattern CP3C extends, the third cross conductive pattern CP3C and the seventh column conductive pattern, which is the third conductive pattern CP3, may be connected to each other. Since the third cross conductive pattern CP3C interconnects between the third conductive patterns CP3, the third cross conductive pattern CP3C may be connected to the seventh column conductive pattern that crosses the third cross conductive pattern CP3C.

As shown in FIG. 1, the first cross conductive pattern CP1C may cross the fifth column conductive pattern, which is the first conductive pattern CP1, while extending from the first column conductive pattern to the ninth column conductive pattern. As the first cross conductive pattern CP1C extends, the first cross conductive pattern CP1C and the fifth column conductive pattern, which is the first conductive pattern CP1, may be connected to each other. Detailed description thereof may be substantially similar to that given above with respect to the third cross conductive pattern CP3C.

Similarly, the fourth cross conductive pattern CP4C may cross the twelfth column conductive pattern, which is the fourth conductive pattern CP4, while extending from the tenth column conductive pattern to the fourteenth column conductive pattern. Also, as the fourth cross conductive pattern CP4C extends, the fourth cross conductive pattern CP4C and the twelfth column conductive pattern, which is the fourth conductive pattern CP4, may be connected to each other. Detailed description thereof may be substantially similar to that given above with respect to the third cross conductive pattern CP3C.

The first conductive pattern CP1, the third conductive pattern CP3, and the fourth conductive pattern CP4 may be wires related to a power system. For example, the first conductive pattern CP1, the third conductive pattern CP3, and the fourth conductive pattern CP4 may each transmit at least one of a power voltage VCCQ, a ground voltage VSSQ, and an external voltage control (EVC).

Therefore, the first upper connection pad 211, the third upper connection pad 213, and the fourth upper connection pad 214 that are electrically and respectively connected to the first conductive pattern CP1, the third conductive pattern CP3, and the fourth conductive pattern CP4 may also be power pads or ground pads, and first chip pads C11, C21, C31, and C41, third chip pads C13, C23, C33, and C43, and fourth chip pads C41, C42, C43, and C44 of semiconductor chips that are electrically and respectively connected to the first conductive pattern CP1, the third conductive pattern CP3, and the fourth conductive pattern CP4 may also be power pads or ground pads.

For example, the first conductive pattern CP1, the first cross conductive pattern CP1C, the first upper connection pad 211, the first chip pads C11, C21, C31, and C41 may be components related to the power voltage VCCQ, the third conductive pattern CP3, the third cross conductive pattern CP3C, the third upper connection pad 213, and the third chip pads C13, C23, C33, and C43 may be components related to the ground voltage VSSQ, and the fourth conductive pattern CP4, the fourth cross conductive pattern CP4C, the fourth upper connection pad 214, and the fourth chip pads C14, C24, C34, and C44 may be components related to the EVC.

The second conductive pattern CP2 may be a wire that transmits a signal containing data. For example, the second conductive pattern CP2 may transmit data signals DQ and data strobe signals DQS that indicate timings for latching the data signals DQ that convey data, addresses, or commands. Therefore, the second upper connection pad 212 electrically connected to the second conductive pattern CP2 may also be a pad that transmits a signal including data, and each of second chip pads C12, C22, C32, and C42 of the semiconductor chips electrically connected to the second conductive pattern CP2 may also be pads that transmit signals including data.

Unlike the semiconductor package 1, in a conventional semiconductor package including a stacked semiconductor chip, the number of chip pads arranged on a semiconductor chip may be identical to the number of upper connection pads connected to the chip pads provided on a package substrate. The upper connection pads provided on the package substrate are larger in size than the chip pads arranged on the semiconductor chip, and the pitch between the upper connection pads is greater than the pitch between the chip pads. Therefore, in a conventional semiconductor package including a stacked semiconductor chip, there is difficulty in connecting the chip pads and the upper connection pads through a conductive pattern extending along the surface of the semiconductor chip or conductive wires.

For example, in a conventional semiconductor package including a stacked semiconductor chip, the width of the semiconductor package in a direction in which the upper connection pads are arranged on the package substrate is greater than the width of the semiconductor package in a direction in which the chip pads are arranged. This limits the margin of configuring a plurality of conductive patterns extending along the surface. Alternatively, a defect may occur due to contact between conductive wires in the connection between the chip pads and the upper connection pads via the conductive wires.

In a conventional semiconductor package including a stacked semiconductor chip, maintaining a sufficient distance between first semiconductor chip pads arranged on a first semiconductor chip and upper connection pads arranged on a package substrate may reduce the configuration limits of conductive patterns and the defects of conductive wires described above. However, in such cases, the size of the package substrate disadvantageously becomes relatively large as compared to a semiconductor chip.

The semiconductor package 1 may reduce the number of upper connection pads for connecting other conductive patterns, excluding a conductive pattern such as the second conductive pattern CP2 through which data-related signals are transmitted, through a cross conductive pattern. In other words, the number of substrate upper connection pads 210 connected to the first semiconductor chip pads via a conductive pattern may be less than the number of first semiconductor chip pads arranged on one semiconductor chip. For example, FIG. 1 shows a total of 14 first semiconductor chip pads on the first semiconductor chip 110 and a total of 8 substrate upper connection pads 210 on the package substrate 200 connected to the first semiconductor chip pads via a conductive pattern.

Even when the size and the pitch of the substrate upper connection pads 210 are greater than the size and the pitch of the first semiconductor chip pads arranged on one semiconductor chip, the width of the semiconductor chip may be similar to or less than the length along which the substrate upper connection pads 210 are arranged. Alternatively, the length in which the first semiconductor chip pads are arranged on the first semiconductor chip 110 in one direction may be similar to or greater than the length of the substrate upper connection pads 210.

For example, in FIG. 1, a first length L1, which is the length of the first semiconductor chip 110 in the first direction, may be approximately equal to or less than a second length L2, which is the length along which the substrate upper connection pads 210 of the package substrate 200 are arranged. Also, the length in which the first semiconductor chip pads are arranged on the first semiconductor chip 110 may be approximately equal to the second length L2.

Therefore, in the semiconductor package 1, the constraint of forming a plurality of conductive patterns extending along the surface the semiconductor chip and the possibility of defects occurring due to contact between conductive wires, which are problems occurring in a conventional semiconductor package described above, may be reduced.

Also, in the semiconductor package 1, the constraint of forming a plurality of conductive patterns and the possibility of defects occurring due to contact between conductive wires, which are problems occurring in a conventional semiconductor package described above, may be reduced without increasing the size of a package substrate.

Therefore, the semiconductor package 1 may reduce the size of a package substrate relative to the size of stacked semiconductor chips, and thus the size of the semiconductor package 1 may be reduced. Also, since the distance between the first semiconductor chip pads and the substrate upper connection pads 210 on the package substrate may be configured to be relatively close, the distance over which electric signals are transmitted may be further reduced, thereby further improving the signal quality of the semiconductor package 1.

In the semiconductor package 1, the same type of conductive patterns may be connected via a plurality of cross conductive patterns. Therefore, normal operation is possible even when some defects occur in some of cross conductive patterns. Therefore, the yield of the semiconductor package 1 may be improved. Also, as the same type of conductive patterns are connected via a plurality of cross conductive patterns, the resistance to signals transmitted by the conductive patterns may be reduced. In other words, since power is supplied and electric signals are transmitted by a plurality of conductive patterns, the semiconductor package 1 may transmit electric signals more smoothly.

FIG. 3 is a plan view of a semiconductor package 1A. FIG. 4A is an enlarged cross-sectional view of the semiconductor package 1A, taken along a line B1-B1′ of FIG. 3. FIG. 4B is an enlarged cross-sectional view of the semiconductor package 1A, taken along a line B2-B2′ of FIG. 3. Descriptions not given below may be substantially identical to descriptions given above.

Referring to FIG. 3, FIG. 4A, and FIG. 4B, the semiconductor package 1A may include the package substrate 200, the first semiconductor chip 110, the second semiconductor chip 120, the third semiconductor chip 130, and the fourth semiconductor chip 140. The semiconductor package 1A does not include the first cross insulation layer PIL1, the third cross insulation layer PIL3, and the fourth cross insulation layer PIL4 included in the semiconductor package 1 of FIG. 1, but may further include a cover insulation layer FIL having a first hole H1, a third hole H3, and a fourth hole H4.

The cover insulation layer FIL may extend along the top surface and the side surfaces of the first semiconductor chip 110, the top surface and the side surfaces of the second semiconductor chip 120, the top surface and the side surfaces of the third semiconductor chip 130, and the top surface and the side surfaces of the fourth semiconductor chip 140. The cover insulation layer FIL may cover at least portions of the top surface and side surfaces of the first semiconductor chip 110, the top surface and the side surfaces of the second semiconductor chip 120, the top surface and the side surfaces of the third semiconductor chip 130, and the top surface and the side surfaces of the fourth semiconductor chip 140 respectively provided with the first conductive pattern CP1, the second conductive pattern CP2, the third conductive pattern CP3, and the fourth conductive pattern CP4. Alternatively, the cover insulation layer FIL may cover all of the top surface and the side surfaces of the first semiconductor chip 110, the top surface and the side surfaces of the second semiconductor chip 120, the top surface and the side surfaces of the third semiconductor chip 130, and the top surface and the side surfaces of the fourth semiconductor chip 140 as a single body. Portions of the separating insulation layer SIL provided on the side surfaces of the first semiconductor chip 110, the side surfaces of the second semiconductor chip 120, the side surfaces of the third semiconductor chip 130, and the side surfaces of the fourth semiconductor chip 140 may be in contact with the cover insulation layer FIL.

The cover insulation layer FIL may cover the first conductive pattern CP1, the second conductive pattern CP2, the third conductive pattern CP3, and the fourth conductive pattern CP4. Also, the cover insulation layer FIL may cover the first semiconductor chip pads of the first semiconductor chip 110, the second semiconductor chip pads of the second semiconductor chip 120, the third semiconductor chip pads of the third semiconductor chip 130, and the fourth semiconductor chip pads of the fourth semiconductor chip 140.

The first cross conductive pattern CP1C, the third cross conductive pattern CP3C, and the fourth cross conductive pattern CP4C may be provided on the cover insulation layer FIL. In other words, the first cross conductive pattern CP1C and other conductive patterns crossing the first cross conductive pattern CP1C may be separated from each other by the cover insulation layer FIL. Similarly, other conductive patterns crossing the third cross conductive pattern CP3C and other conductive patterns crossing the fourth cross conductive pattern CP4C may be separated from the third cross conductive pattern CP3C and the fourth cross conductive pattern CP4C by the cover insulation layer FIL, respectively.

The first hole H1, the third hole H3, and the fourth hole H4 may be provided in portions of the cover insulation layer FIL adjacent to both ends of the first cross conductive pattern CP1C, the third cross conductive pattern CP3C, and the fourth cross conductive pattern CP4C, respectively. The first hole H1 may be provided in the cover insulation layer FIL such that first cross conductive patterns CP1C are connected to the first conductive patterns CP1, respectively. Similarly, the third hole H3 may be provided in the cover insulation layer FIL such that both ends of the third cross conductive pattern CP3C are connected to the third conductive patterns CP3, respectively. The fourth hole H4 may be provided in the cover insulation layer FIL such that fourth cross conductive patterns CP4C are connected to the fourth conductive patterns CP4, respectively.

The first cross conductive pattern CP1C may extend from the first column conductive pattern to the ninth column conductive pattern and cross second to eighth column conductive patterns. The first cross conductive pattern CP1C may be connected to a conductive pattern, which is the first conductive pattern CP1, from among the second to eighth column conductive patterns. For example, since the fifth column conductive pattern is the first conductive pattern CP1, the first cross conductive pattern CP1C may be connected to the fifth column conductive pattern through the first hole H1 provided in the cover insulation layer FIL.

The third cross conductive pattern CP3C may extend from the third column conductive pattern to the eleventh column conductive pattern and cross fourth to tenth column conductive patterns. The third cross conductive pattern CP3C may be connected to a conductive pattern, which is the third conductive pattern CP3, from among the fourth to tenth column conductive patterns. For example, since the seventh column conductive pattern is the third conductive pattern CP3, the third cross conductive pattern CP3C may be connected to the seventh column conductive pattern through the third hole H3 provided in the cover insulation layer FIL. Similarly, since the twelfth column conductive pattern is the fourth conductive pattern CP4, the fourth cross conductive pattern CP4C may be connected to the twelfth column conductive pattern through the fourth hole H4 provided in the cover insulation layer FIL.

Although FIG. 3 shows that the first hole H1, the third hole H3, and the fourth hole H4 have greater widths than the widths of the first conductive pattern CP1, the third conductive pattern CP3, and the fourth conductive pattern CP4, respectively, this is only illustration. As shown in FIG. 3, the sizes of the first hole H1, the third hole H3, and the fourth hole H4 may be provided to be greater than the widths of the first conductive pattern CP1, the third conductive pattern CP3, and the fourth conductive pattern CP4, respectively. Alternatively, unlike as in FIG. 3, the sizes of the first hole H1, the third hole H3, and the fourth hole H4 may be provided to be equal to or less than the widths of the first conductive pattern CP1, the third conductive pattern CP3, and the fourth conductive pattern CP4, respectively. The side surface of the third hole H3 provided in the cover insulation layer FIL and the third cross conductive pattern CP3C may contact each other.

FIG. 5 is a plan view of a semiconductor package 1B. FIG. 6 is an enlarged cross-sectional view of the semiconductor package 1B, taken along a line D-D′ of FIG. 5. Descriptions not given below may be substantially identical to descriptions given above.

Referring to FIGS. 5 and 6, the semiconductor package 1B may include the package substrate 200, the first semiconductor chip 110, the second semiconductor chip 120, the third semiconductor chip 130, and the fourth semiconductor chip 140. The semiconductor package 1B may further include the first cross insulation layer PIL1, the third cross insulation layer PIL3, and the fourth cross insulation layer PIL4.

As described above, the first column conductive pattern, the fifth column conductive pattern, and the ninth column conductive pattern are the first conductive patterns CP1, and the first column conductive pattern, the fifth column conductive pattern, and the ninth column conductive pattern may be connected via the first cross conductive pattern CP1C. For example, the first cross conductive pattern CP1C may be disposed between the first column conductive pattern and the ninth column conductive pattern arranged on the first semiconductor chip 110, and, as the first cross conductive pattern CP1C crosses the fifth column conductive pattern, the first cross conductive pattern CP1C may be connected to the fifth column conductive pattern.

The first cross conductive pattern CP1C of the semiconductor package 1B may be provided on the first semiconductor chip pads. The first cross conductive pattern CP1C of the semiconductor package 1B may be arranged between the first column chip pad and the ninth column chip pad arranged on the first semiconductor chip 110. In the lengthwise direction of the first cross conductive pattern CP1C, both ends of the first cross conductive pattern CP1C may be located on the first column chip pad and the ninth column chip pad, which are the first chip pads C11. The first cross conductive pattern CP1C may interconnect between the first chip pads C11 provided on the same semiconductor chip.

The first cross conductive pattern CP1C on the first semiconductor chip pads may be separated from second to fourth column chip pads and sixth to eighth column chip pads. A portion of the first cross conductive pattern CP1C on the first semiconductor chip pads may be extended and connected to the fifth column chip pad.

The first cross conductive pattern CP1C on the first semiconductor chip pads may cross second to eighth column conductive patterns. The first cross insulation layer PIL1 may be provided between the first cross conductive pattern CP1C and the second to fourth column conductive patterns and the sixth to eighth column conductive patterns.

The first cross insulation layer PIL1 may separate the first cross conductive pattern CP1C on the first semiconductor chip pads from other conductive patterns. The first cross conductive pattern CP1C on the third semiconductor chip pads is also separated by the first cross insulation layer PIL1. For example, as shown in FIG. 6, on the third semiconductor chip 130, the first cross conductive pattern CP1C passes over second to fourth chip pads and sixth to eighth chip pads, and the first cross insulation layer PIL1 may fill spaces between the first cross conductive pattern CP1C and wires other than the first conductive pattern CP1. Therefore, the first cross insulation layer PIL1 may separate the first cross conductive pattern CP1C from other wires other than the first conductive pattern CP1, and the first cross insulation layer PIL1 may separate the first cross conductive pattern CP1C from chip pads other than the first chip pad C31 of the third semiconductor chip 130.

Substantially identical to the first cross conductive pattern CP1C being provided on the first semiconductor chip pads of the first semiconductor chip 110 described above, the first cross conductive pattern CP1C may be provided on the second semiconductor chip pads of the second semiconductor chip 120, and the first cross conductive pattern CP1C may be provided on the third semiconductor chip pads of the third semiconductor chip 130.

Although FIGS. 5 and 6 show the first cross conductive pattern CP1C disposed on the first semiconductor chip pads, the second semiconductor chip pads, and the third semiconductor chip pads, it will be understood that the third cross conductive pattern CP3C and the fourth cross conductive pattern CP4C may also be disposed on the first semiconductor chip pads as needed. Also, it will be understood cross conductive patterns may be provided on the second semiconductor chip pads, the third semiconductor chip pads, and the fourth semiconductor chip pads in addition to the first semiconductor chip pads.

The semiconductor package 1B may include a relatively large number of cross conductive patterns. Also, since a region in which a cross conductive pattern may be provided is expanded on each semiconductor chip, the overall size of the semiconductor package 1B may be reduced.

FIGS. 7A to 7D are plan views sequentially showing a method for manufacturing the semiconductor package 1. Descriptions not given below may be substantially identical to descriptions given above.

Referring to FIG. 7A, a semiconductor chip stack including the first semiconductor chip 110, the second semiconductor chip 120, the third semiconductor chip 130, and the fourth semiconductor chip 140 is provided on the package substrate 200, and the semiconductor chip stack may be stacked in a step-like shape.

Referring to FIG. 7B, the first conductive pattern CP1, the second conductive pattern CP2, the third conductive pattern CP3, and the fourth conductive pattern CP4 may be formed to extend along the top surface and side surfaces of the first semiconductor chip 110, the top surface and side surfaces of the second semiconductor chip 120, the top surface and side surfaces of the third semiconductor chip 130, and the top surface and side surfaces of the fourth semiconductor chip 140, respectively.

Although not shown in FIG. 7B, before the first conductive pattern CP1, the second conductive pattern CP2, the third conductive pattern CP3, and the fourth conductive pattern CP4 are formed, the separating insulation layer SIL described above with reference to FIG. 2B may be first formed on the top surface and side surfaces of the first semiconductor chip 110, the top surface and side surfaces of the second semiconductor chip 120, the top surface and side surfaces of the third semiconductor chip 130, and the top surface and side surfaces of the fourth semiconductor chip 140.

The first conductive pattern CP1, the second conductive pattern CP2, the third conductive pattern CP3, and the fourth conductive pattern CP4 extending to the top surface of the package substrate 200 and respectively corresponding to the first upper connection pad 211, the second upper connection pad 212, the third upper connection pad 213, and the fourth upper connection pad 214 may be formed to be respectively connected to the first upper connection pad 211, the second upper connection pad 212, the third upper connection pad 213, and the fourth upper connection pad 214.

For example, a first seed layer for conductive patterns may be first formed at locations where the first conductive pattern CP1, the second conductive pattern CP2, the third conductive pattern CP3, and the fourth conductive pattern CP4 are to be formed, and then conductive patterns may be formed on the first seed layer.

Referring to FIG. 7C, the first cross insulation layer PIL1, the third cross insulation layer PIL3, and the fourth cross insulation layer PIL4 may be first formed at locations where the first cross conductive pattern CP1C, the third cross conductive pattern CP3C, and the fourth cross conductive pattern CP4C are to be formed, respectively. The first cross insulation layer PIL1, the third cross insulation layer PIL3, and the fourth cross insulation layer PIL4 may include at least one parylene, Teflon, and an epoxy mold compound. The first cross insulation layer PIL1, the third cross insulation layer PIL3, and the fourth cross insulation layer PIL4 may be formed by using various methods such as CVD, spin coating, spray coating, and dipping.

The semiconductor package 1A of FIG. 3 may be manufactured by forming the cover insulation layer FIL that extends along the top surface and the side surfaces of the first semiconductor chip 110, the top surface and the side surfaces of the second semiconductor chip 120, the top surface and the side surfaces of the third semiconductor chip 130, and the top surface and the side surfaces of the fourth semiconductor chip 140, rather than the first cross insulation layer PIL1, the third cross insulation layer PIL3, and the fourth cross insulation layer PIL4. In some implementations, the first hole H1, the third hole H3, and the fourth hole H4 may be formed by removing portions of the cover insulation layer FIL using a laser.

Referring to FIG. 7D, the first cross conductive pattern CP1C, the third cross conductive pattern CP3C, and the fourth cross conductive pattern CP4C may be formed on the first cross insulation layer PIL1, the third cross insulation layer PIL3, and the fourth cross insulation layer PIL4, respectively. A second seed layer may be first formed on the first cross insulation layer PIL1, the third cross insulation layer PIL3, and the fourth cross insulation layer PIL4 at respective locations where the first cross conductive pattern CP1C, the third cross conductive pattern CP3C, and the fourth cross conductive pattern CP4C are to be formed, and then cross conductive patterns may be formed on the second seed layer.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to embodiments thereof, it will be understood that various changes in form and details may be made therein without departing from the spirit and scope of the following claims.

What is claimed is:

1. A semiconductor package comprising:
a package substrate having at least one first upper connection pad and at least one second upper connection pad provided on a top surface of the package substrate;
a first semiconductor chip disposed on the package substrate;
a second semiconductor chip provided on the first semiconductor chip and laterally offset in a first direction from the first semiconductor chip;
a plurality of first chip pads and a plurality of second chip pads provided on a top surface of the first semiconductor chip and a top surface of the second semiconductor chip, respectively;
a plurality of first conductive patterns extending along the top surface and side surfaces of the first semiconductor chip and the top surface and side surfaces of the second semiconductor chip, the plurality of first conductive patterns being connected to the first chip pad of the first semiconductor chip, the first chip pad of the second semiconductor chip, and the at least one first upper connection pad;
a plurality of second conductive patterns extending along the top surface and the side surfaces of the first semiconductor chip and the top surface and the side surfaces of the second semiconductor chip, the plurality of second conductive patterns being connected to the plurality of second chip pads of the first semiconductor chip, the plurality of second chip pads of the second semiconductor chip, and the at least one second upper connection pad; and
a cross conductive pattern, wherein both ends of the cross conductive pattern are respectively connected to the plurality of first conductive patterns,
wherein the cross conductive pattern is disposed on the top surface of the first semiconductor chip and at least one of the plurality of second conductive patterns,
wherein the cross conductive pattern crosses at least one of the plurality of second conductive patterns, and
wherein both ends of the cross conductive pattern are spaced apart from at least one of the plurality of second conductive patterns.

2. The semiconductor package of claim 1, wherein a number of the at least one first upper connection pad is less than a number of first chip pads connected to a plurality of first conductive patterns provided on the first semiconductor chip.

3. The semiconductor package of claim 1, wherein at least a portion of the plurality of first conductive patterns and at least a portion of the plurality of second conductive patterns are elongated in the first direction.

4. The semiconductor package of claim 1, wherein some of the plurality of first conductive patterns connected to the plurality of first chip pads provided on the first semiconductor chip are spaced apart from the top surface of the package substrate, and
wherein the plurality of first conductive patterns extending from the plurality of second chip pads on the first semiconductor chip are all connected to the at least one second upper connection pad.

5. The semiconductor package of claim 1, wherein a number of the plurality of second chip pads on the first semiconductor chip is identical to a number of the at least one second upper connection pad.

6. The semiconductor package of claim 1, wherein the cross conductive pattern crosses the plurality of second conductive patterns and the plurality of first conductive patterns, and
wherein the cross conductive pattern is connected to the plurality of first conductive patterns.

7. The semiconductor package of claim 1, wherein at least some of the plurality of first conductive patterns and the plurality of second conductive patterns contact the top surface of the package substrate, and
wherein the plurality of first conductive patterns and the plurality of second conductive patterns contacting the top surface of the package substrate comprise at least one of straight portions and bent portions.

8. The semiconductor package of claim 1, wherein the plurality of first chip pads and the plurality of second chip pads on the first semiconductor chip are respectively connected, via bonding wires, to the at least one first upper connection pad and the at least one second upper connection pad, respectively.

9. The semiconductor package of claim 1, wherein the plurality of first conductive patterns, the plurality of second conductive patterns, and the cross conductive pattern comprise seed layers extending from lower portions of the plurality of first conductive patterns, the plurality of second conductive patterns, and the cross conductive pattern.

10. The semiconductor package of claim 1, further comprising a cross insulation layer disposed between the cross conductive pattern and a second conductive pattern of the plurality of second conductive patterns,
wherein the cross insulation layer covers a top surface of the second conductive pattern.

11. The semiconductor package of claim 10, wherein a width of the cross insulation layer is greater than a width of the cross conductive pattern.

12. The semiconductor package of claim 1, further comprising a separating insulation layer disposed between the plurality of first conductive patterns and the first semiconductor chip, between the plurality of first conductive patterns and the second semiconductor chip, between the plurality of second conductive patterns and the first semiconductor chip, and between the plurality of second conductive patterns and the second semiconductor chip,
wherein the separating insulation layer is disposed on the side surfaces of the first semiconductor chip and the side surfaces of the second semiconductor chip.

13. The semiconductor package of claim 1, further comprising a cover insulation layer covering the plurality of first conductive patterns and the plurality of second conductive patterns,
wherein the cover insulation layer extends along the top surface and the side surfaces of the first semiconductor chip and the top surface and the side surfaces of the second semiconductor chip,
wherein the cover insulation layer is disposed between the cross conductive pattern and the plurality of second conductive patterns, and
wherein a plurality of first holes vertically extend through the cover insulation layer and are arranged between the cross conductive pattern and a plurality of first conductive patterns.

14. The semiconductor package of claim 1, wherein both ends of the cross conductive pattern are respectively disposed on the first chip pads, and both ends of the cross conductive pattern are respectively connected to the first chip pads, and
wherein the cross conductive pattern is disposed on the plurality of second chip pads, the cross conductive pattern is spaced apart from the plurality of second chip pads, and a cross insulation layer is disposed between the cross conductive pattern and the plurality of second chip pads.

15. The semiconductor package of claim 1, wherein signals are configured to be transmitted between the plurality of first chip pads and the at least one first upper connection pad through the plurality of first conductive patterns and the cross conductive pattern, and
wherein signals are configured to be transmitted between the plurality of second chip pads and the at least one second upper connection pad through the plurality of second conductive patterns.

16. The semiconductor package of claim 15, wherein the at least one first upper connection pad is configured to transmit either ground signals or power signals or transmit both of the ground signals and the power signals, and
the at least one second upper connection pad is configured to transmit data signals.

17. A semiconductor package comprising:
a package substrate having a plurality of first upper connection pads and a plurality of second upper connection pads disposed on a top surface of the package substrate;
a plurality of semiconductor chip stacks comprising a plurality of semiconductor chips stacked in a step-like shape and disposed on the package substrate,
wherein the plurality of semiconductor chips comprise a first semiconductor chip and a second semiconductor chip that are sequentially stacked, and the first semiconductor chip is disposed on the package substrate;
a plurality of first chip pads and a plurality of second chip pads respectively disposed on top surfaces of the plurality of semiconductor chips;
a plurality of first conductive patterns extending along a top surface and side surfaces of the first semiconductor chip and a top surface and side surfaces of the second semiconductor chip, the plurality of first conductive patterns being connected to the first chip pad of the first semiconductor chip, the first chip pad of the second semiconductor chip, and the plurality of first upper connection pads;
a plurality of second conductive patterns extending along the top surface and the side surfaces of the first semiconductor chip and the top surface and the side surfaces of the second semiconductor chip, the plurality of second conductive patterns being connected to the second chip pad of the first semiconductor chip, the second chip pad of the second semiconductor chip, and the plurality of second upper connection pads; and
a cross conductive pattern, wherein both ends of the cross conductive pattern are connected to at least one of the plurality of first conductive patterns,
wherein the cross conductive pattern is disposed on the top surface of the first semiconductor chip and at least one of the plurality of second conductive patterns,
wherein the cross conductive pattern crosses at least one of the plurality of second conductive patterns, and both ends of the cross conductive pattern are respectively connected to the plurality of first conductive patterns and are spaced apart from at least one of the second conductive patterns,
wherein the plurality of semiconductor chips are stacked in a step-like shape and offset from each other in a first direction,
wherein at least a portion of each of the plurality of first conductive patterns and at least a portion of each of the plurality of second conductive patterns extend on the first semiconductor chip and the second semiconductor chip and are elongated in the first direction, and
wherein a number of the plurality of second chip pads on the first semiconductor chip is identical to a number of the plurality of second upper connection pads.

18. The semiconductor package of claim 17, wherein some of the plurality of first conductive patterns connected to the plurality of first chip pads disposed on the first semiconductor chip is spaced apart from the top surface of the package substrate,
the plurality of first conductive patterns extending from the plurality of second chip pads on the first semiconductor chip are all connected to the plurality of second upper connection pads, and
wherein a number of the first upper connection pads is equal to or less than a number of a plurality of first chip pads connected to the plurality of first conductive patterns disposed on the first semiconductor chip.

19. The semiconductor package of claim 17, wherein signals are configured to be transmitted between the plurality of first chip pads and the plurality of first upper connection pads through the plurality of first conductive patterns and the cross conductive pattern,
wherein signals are configured to be transmitted between the plurality of second chip pads and the plurality of second upper connection pads through the plurality of second conductive patterns,
wherein the plurality of first upper connection pads are configured to transmit either ground signals or power signals or transmit both of the ground signals and the power signals,
wherein the plurality of second upper connection pads are configured to transmit data signals, and
wherein a cross insulation layer is disposed between the cross conductive pattern and the plurality of second conductive patterns, and the cross insulation layer covers at least a portion of the top surface of the first semiconductor chip.

20. A semiconductor package comprising:
a package substrate having a plurality of first upper connection pads and a plurality of second upper connection pads disposed on a top surface of the package substrate;
a plurality of semiconductor chip stacks comprising a plurality of semiconductor chips stacked in a step-like shape and disposed on the package substrate,
wherein the plurality of semiconductor chips comprise a first semiconductor chip and a second semiconductor chip that are sequentially stacked, and the first semiconductor chip is disposed on the package substrate;
a plurality of first chip pads and a plurality of second chip pads respectively disposed on top surfaces of the plurality of semiconductor chips;
a plurality of first conductive patterns extending along a top surface and side surfaces of the first semiconductor chip and a top surface and side surfaces of the second semiconductor chip, the plurality of first conductive patterns being connected to the first chip pad of the first semiconductor chip, the first chip pad of the second semiconductor chip, and the plurality of first upper connection pads;
a plurality of second conductive patterns extending along the top surface and the side surfaces of the first semiconductor chip and the top surface and the side surfaces of the second semiconductor chip, the plurality of second conductive patterns being connected to the second chip pad of the first semiconductor chip, the second chip pad of the second semiconductor chip, and the plurality of second upper connection pads; and
a cross conductive pattern, wherein both ends of the cross conductive pattern are connected to at least one of the plurality of first conductive patterns,
wherein the cross conductive pattern is disposed on the top surface of the first semiconductor chip and the second conductive pattern,
wherein the cross conductive pattern crosses the plurality of second conductive patterns, and both ends of the cross conductive pattern are respectively connected to the plurality of first conductive patterns and are spaced apart from at least one of the plurality of second conductive patterns,
wherein the plurality of semiconductor chips are stacked in a step-like shape and offset from each other in a second direction,
wherein at least a portion of the first conductive pattern and at least a portion of the second conductive pattern elongated on the first semiconductor chip and the second semiconductor chip elongated in the second direction,
wherein a number of the plurality of second chip pads on the first semiconductor chip is identical to a number of the plurality of second upper connection pads,
wherein a cross insulation layer is disposed between the cross conductive pattern and the plurality of second conductive patterns, the cross insulation layer covers the top surface of the plurality of second conductive patterns, and a width of the cross insulation layer is greater than a width of the cross conductive pattern, and
wherein a separating insulation layer is disposed on side surfaces of the first semiconductor chip and side surfaces of the second semiconductor chip.
